(19) United States
(12) Patent Application Publication
(10) Pub. No.: US 2004/0029310 A1
(43) Pub. Date: Feb. 12, 2004

(54) Organic field-effect transistor (ofet), a production method therefor, an integrated circut constructed from the same and their uses

(76) Inventors: Adoft Bernds, Bajersdorf (DE); Wolfgang Clemens, Puschendorf (DE); Walter Fix, Furth (DE); Henning Rost, Erlangen (DE)

Correspondence Address: YOUNG & THOMPSON, 745 SOUTH 23RD STREET 2ND FLOOR, ARLINGTON, VA, 22202

(21) Appl. No.: 10/344,951

(22) PCT Filed: Aug. 17, 2001
(86) PCT No.: PCT/DE01/03163

(30) Foreign Application Priority Data
Aug. 18, 2000 (DE) 10040441.3
Nov. 20, 2000 (DE) 10057502.1
Nov. 21, 2000 (DE) 10057665.6

(51) Int. Cl. H01L 51/40

(52) U.S. Cl. 438/99

(57) ABSTRACT

The invention relates to an organic field-effect transistor with an improved performance. The output current is increased by the arrangement of several current channels on the OFET, all of which contribute to the output current. By positioning the source and drain electrode on a plane which is not parallel to the surface of the substrate, it is possible to reduce the distances between the source and the drain in relation to those previously attainable. This produces shorter current channels with faster switching speeds. Finally, the invention relates to integrated circuits, which are stacked on a substrate to save space.

The invention relates to an organic field-effect transistor (OFET) with improved performance.

Organic integrated circuits (plastic integrated circuits PIC) based on OFETs are used for microelectronic mass applications and disposal products such as contactlessly readable identification and product “tags” (RFID tags: radiofrequency identification tags). In this case, the excellent operating behavior of silicone technology can be dispensed with, but by the same token very low production costs and mechanical flexibility should be ensured. The components, such as e.g. electronic bar codes, are typically disposal products.

To date, the performance of OFETs has been limited because the organic semiconductor materials used for these components have only a low charge carrier mobility. This is manifested inter alia in the fact that the output currents of the OFETs are relatively low. The higher the output currents of an OFET, the faster the electrical circuit constructed therefrom becomes. A further advantage is that with high output currents it is also possible directly to drive components which require high currents, such as e.g. organic light-emitting diodes (OLEDs) for active displays.

An important application of the OFET is an organic transponder (RFID tag). The faster these transponders operate, the shorter the time required to identify an object/merchandise/article. Previously known organic circuits based on OFETs have a maximum switching speed of 100 bit/s (Philips: Gelinck et al., APL 77, pp. 1487 89, 9/2000). That is much too slow for the rapid detection of items of merchandise/articles since 128 bits typically have to be transmitted. A read-out time of about 0.1-0.05 s should be sought. Very fast OFETs are needed for this.

The switching speed of an OFET is determined by the transit time of the charge carriers from the source electrode to the drain electrode and is thus dependent on the mobility of the semiconducting material and also on the channel length of the current channel, to be precise in such a way that a longer current channel leads to a lower switching frequency, and vice versa. In principle, high switching frequencies are sought because quite a lot of applications of the OFET depend on the switching speed thereof and hitherto the application of the OFETs has been greatly limited owing to the low switching frequency, because generally, in information processing, the bit rate required for a usable transmission lies at least in the kbit/s range.

The OFET with a current channel running laterally, that is to say horizontally and parallel to the substrate surface, has previously been disclosed, for example in DE 10040441.3. The sole current channel arises between the source and drain electrodes, which, in the case of the previously disclosed systems, lie in one plane and parallel to the plane of the substrate surface. The distance between source and drain determines the length of the current channel, a minimum length of the current channel of at least 1 μm having been achieved heretofore with the patterning methods. Transistor switching frequencies in the region of about 10 kHz have thus been achieved. However, these switching frequencies are still too low for many applications.

It is an object of the invention to increase the performance, in particular the output currents and switching frequency of an OFET by improving the “layout” of the OFET and the circuit constructed therefrom.

The invention relates to an organic field-effect transistor on a substrate, at least one semiconducting layer connecting at least one drain and one source electrode, at least two insulating layers and at least one conductive layer with a gate electrode being applied on the substrate in such a way that after a voltage has been applied to the gate electrode, the field effect gives rise to at least two current channels and/or a current channel running vertically, that is to say transversely with respect to the surface of the substrate.

Moreover, the invention relates to a method for producing a multiple channel OFET by applying patterned organic layers (e.g. polymer layers) to a substrate, and/or to a method for producing an OFET having a current channel running transversely with respect to the substrate surface.

Furthermore, the invention relates to an integrated circuit having at least two transistors which are arranged in stacked fashion.

Finally, the invention also relates to the use of the OFET with at least two and/or one vertical current channel in the construction of logic circuits and/or in the driving of organic displays, and to the use in a fast transponder and/or an RFID tag.

According to one embodiment, the method for producing an OFET comprises the following work steps:

application of a lower electrode to a substrate,

application of a first layer made of insulator to the lower electrode,

application of an upper electrode to the first insulator,

patterning of the upper electrode and of the first insulator layer,

connection of the two electrodes by a coating with semiconducting material,

covering of the semiconducting layer with the second insulator,

application of the gate electrode to the second insulator where the semiconducting layer connects the other two electrodes.

Preferably, with the use of the OFET with at least two and/or one vertically running current channel in an integrated organic circuit, it is possible to process information at a speed of at least 10 kbit/s.

In the known layouts for an OFET, the source and drain electrodes lie on one plane which is approximately parallel to the plane of the substrate surface. The distance between the two electrodes is kept as small as possible and is essentially dependent on the fineness or resolution of the patterning method and is thus a crucial cost factor in the production of the OFET, because the finer patterning methods are the more costly.

A production of a distance between source and drain of less than 1 μm has been possible heretofore only with a costly patterning method.

By means of the OFET with a vertical current channel that is proposed for the first time here, it is possible to realize significantly shorter distances between drain and source, such as, for example, approximately 100 nm to approximately 1 μm, highly cost-effectively by the choice of the layer thickness.

This is possible because the channel length, which mirrors the distance between the source and drain electrodes, does not depend on the resolution of the expensive and complicated photolithography patterning methods, but rather very simply on the layer thickness of the insulator layer which is applied between source and drain.

If this layout is combined with a semiconductor made of organic material, which preferably has a mobility of 10(−2) cm2/Vs, it is possible to produce OFETs with a switching speed of the kind that are of interest for applications in transponders.

Preferably, two or more current channels of an OFET are produced by at least two gate electrodes.

According to one embodiment of the OFET, both sides of a gate electrode are used for producing current channels.

According to a further embodiment, an OFET has at least two current channels with different geometries.

By virtue of the arrangement of two or more current channels and/or by virtue of the reduction of the length of the current channel or the vertical arrangement thereof, the output currents and/or the switching frequency can be increased independently of the material used.

The additional current channels can be produced by a plurality of gate electrodes or by using both sides of a gate electrode. When using two or more gate electrodes, the latter are preferably short-circuited. As a result, the different current channels can be controlled by just one gate voltage. Moreover, an additional transistor terminal is avoided by virtue of the gate electrodes being shorted together. As a result, the multichannel OFET can be integrated into existing circuit concepts in a simple manner.

An OFET is produced by patterned application of organic layers (e.g. polymer and/or oligomer layers), or generally by coating with insulating, semiconducting and/or conductive plastic layers. This is preferably achieved by means of a printing technique or by application such as spin-on, vapor deposition, pouring on, spin-coating or sputtering on with subsequent photolithography.

During the production of one embodiment of an OFET as a multichannel OFET, the patterned layers are applied for example in the following order:

Firstly, a gate electrode is applied to a substrate. An insulator layer is then applied to the gate electrode, which insulator layer is larger than the gate electrode in one direction and is smaller than the gate electrode in the direction perpendicular thereto. The insulator layer has applied to it at least one source electrode and at least one drain electrode in such a way that the lower gate electrode lies approximately centered between source and drain electrodes.

The electrode can be patterned for example by photolithography, printing and/or by use of a doctor blade.

A semiconductor layer is then applied between the source electrode and the drain electrode, the semiconductor layer overlapping the source and drain electrodes by a few micrometers. A further, upper insulator layer is applied to the semiconductor layer.

An upper gate electrode is preferably applied to the upper insulator layer in such a way that a short circuit to the lower gate electrode is produced by overlapping.

The first insulator, whose layer thickness determines the channel length in the case of an OFET with a vertical current channel, is applied to the lower electrode for example by spin-on or use of a doctor blade and likewise patterned. The first insulator can be patterned either in a separate work step or together with the adjoining drain electrode layer.

In this case, the first insulator can also be applied by printing, for example.

The semiconducting layer can be applied for example by spin-on or the use of a doctor blade and be patterned with the aid of photolithography.

The second insulator layer can likewise be spun on or applied by the use of a doctor blade.

Finally, the gate electrode can be applied by sputtering on, vapor deposition, or printing.

The source/drain electrode may comprise conductive organic material and/or a metallic conductor.

Polyimide, polyester and/or polymethacrylate is used as insulator.

Either metal or a conductive plastic is used as gate.

An organic material with a high charge carrier mobility is preferably employed as semiconducting layer.

Polyaniline is preferably used as conductive layer.

In this case, the term “organic material” encompasses all types of organic, organometallic and/or inorganic plastics. All types of substances are involved with the exception of the semiconductors which form the traditional diodes (germanium, silicone), and the typical metallic conductors. Accordingly, a restriction in the dogmatic sense to organic material as carbon-containing material is not envisaged, rather the broad use of e.g. silicones is also imagined. Furthermore, the term is not intended to be subject to any restriction with regard to the molecule size, in particular to polymeric and/or oligomeric materials, or rather the use of “small molecules” is also entirely possible.

In an integrated circuit, the surface of the substrate limits the number of transistors which together produce the integrated circuit, because the transistors are only arranged one beside the other and at a minimum distance, so that the field effect of one transistor does not disturb an adjacent transistor, or vice versa. This has the disadvantage that the two-dimensional, that is to say areal, space requirement of the integrated circuit is relatively high.

By stacking transistors, the usable area of a substrate can be doubled or multiplied, because the transistors can be arranged not only one beside the other but also one above the other. In this case, the term “multiplying” does not just refer to integer multiples.

When stacking OFETs the encapsulation and/or covering of the lower OFET may, for example, serve as substrate and/or carrier for the upper OFET. In this case, the thickness and the material of the encapsulation are chosen such that it does not permit a field effect from the gate electrode of the lower transistor to the drain or source electrode of the upper transistor. Accordingly, the thickness of the encapsulating and/or insulating layer is chosen such that it is far greater than that of the insulator layer between the gate electrode and the source/drain electrodes of an OFET. The thickness of the layer between two stacked transistors is preferably far in excess of 200 nm, for example in the range between 400 and 800 nm, in particular approximately 600 nm.

An insulator layer is preferably used as material for the encapsulation. Materials for this are the customary insulators in organic semiconductor technology, such as e.g. polyvinyl phenol (PVP).

The invention will be explained in more detail below using exemplary embodiments:

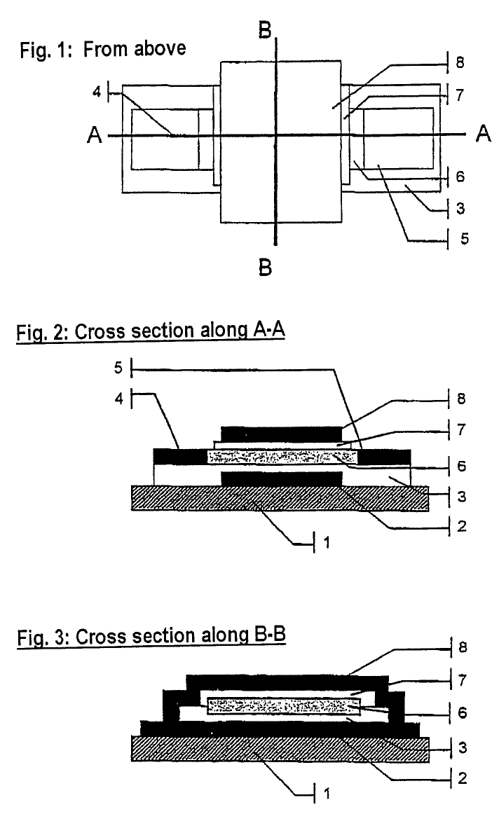

FIGS. 1 to 3 illustrate the construction and the layout of a multiple channel OFET using the example of a double channel OFET, FIGS. 4 to 6 an OFET with at least one vertical current channel and, finally, FIG. 7 reveals an integrated circuit comprising at least two transistors which are arranged in a stacked fashion:

FIG. 1 shows a double channel OFET from above,

FIG. 2 shows a cross section through the OFET along the line A-A

FIG. 3 shows a cross section along the line B-B.

FIG. 4 shows the layer construction of an OFET with a vertical current channel.

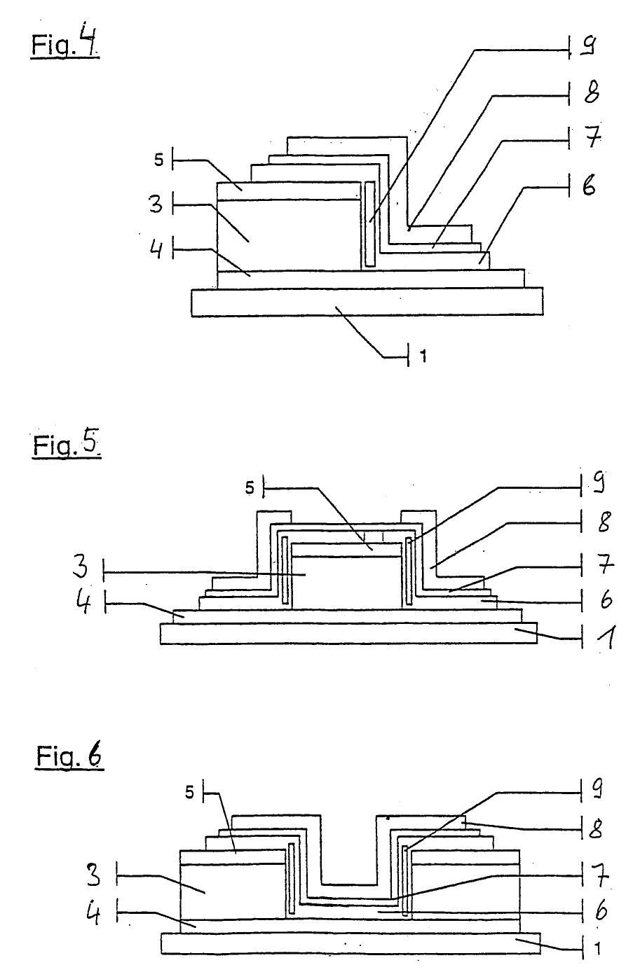

FIG. 5 shows an exemplary embodiment of a layout of an OFET with two vertical current channels.

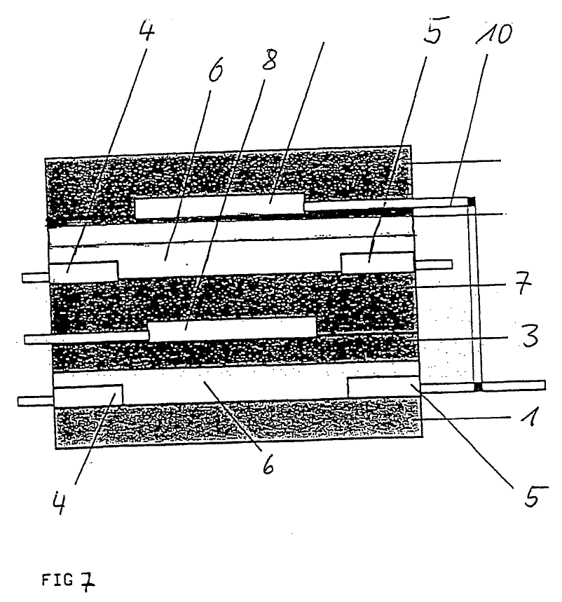

FIG. 6 shows a further variant of an OFET with two vertical current channels.

Finally, FIG. 7 shows a cross section through two organic field-effect transistors stacked one on top of the other:

FIG. 1 reveals the three electrodes of a transistor: the source electrode 4, the drain electrode 5 and a gate electrode 8, which is short-circuited e.g. with the gate electrode 2 (see FIG. 3). Furthermore, the upper insulator layer 7 can be seen, which prevents an electrical contact between the gate electrode 8 and the semiconductor 6.

FIG. 2 reveals the layout of the double channel OFET in a cross section along the line A-A of FIG. 1. Situated right at the bottom is the substrate 1, which may be made e.g. of glass, ceramic, Si wafer or an organic material such as e.g. polyamide or polyethylene terephthalate (PET) film. Situated on the substrate 1 is the lower insulator layer 3, which may comprise e.g. polyvinyl phenol. As generally in the case of OFET electrodes, the lower and upper gate electrodes may be made e.g. of conductive polymers such as polyaniline (PAni). The two gate electrodes give rise, through the field effect, to two current channels: one on the top side and one on the underside of the semiconductor layer 6. As a result, an increase in the output current is effected according to the invention. In this cross section, the lower gate electrode is completely enclosed by the lower insulator 3 and the substrate 1. Situated on the lower insulator layer is the semiconductor 6 (e.g. poly-3-hexylthiophene) with the two electrodes 4 and 5 (source and drain) and, as subsequent layer, one discerns the upper insulator layer 7 and, on the latter, the upper gate electrode 8.

FIG. 3 shows a cross section through the double channel OFET from FIG. 1 along the line B-B.

The (flexible) substrate 1 can again be discerned right at the bottom, and lying on said substrate is the lower gate electrode 2, which is adjoined by the upper gate electrode 8. Encapsulated by the gate electrodes are: the lower and upper insulation layers 3 and 7, which, for their part, completely enclose the semiconductor 6 (in cross section).

FIG. 4 reveals the following layer construction from bottom to top:

Applied on the substrate 1 is the source electrode 4. On, this layer and in contact with the source electrode 4 is the first insulator layer 3 and the semiconducting layer 6. The first insulator layer 3 is adjoined by the drain electrode 5, which, for its part, is also in contact with the semiconducting layer 6. The semiconducting layer 6 is thus in contact with the two electrodes source 4 and drain 5 and also with the first insulator layer 3 which isolates them. However, source 4 and drain 5 are not in contact with one another, but rather are electrically insulated from one another by the first insulator layer 3. These two electrodes are connected only by the semiconducting layer 6. The thickness 1 of the first insulator layer 3 corresponds to the length of the current channel 9, which forms, after a voltage has been applied to the gate electrode 8, through the field effect between the source electrode 4 and the drain electrode 5 in the semiconducting material 6.

The second insulator layer 7 bears on the semiconducting layer 6 and insulates the semiconducting layer 6 from the gate electrode 8.

FIG. 5 shows an exemplary embodiment of a layout of an OFET with two vertical current channels.

The layer construction from bottom to top again shows the substrate 1, adjoining the latter the source electrode 4, on which the first insulator layer 3 and the drain electrode 5 are applied in patterned fashion. The layers 3, 4 and 5 are coated with semiconducting material 6. The semiconductor 6 is coated with a second insulator 7. Two gate electrodes 8 are applied in patterned fashion on the second insulator 7, so that two vertical current channels 9 are formed.

In the case of the variant shown in FIG. 6, two vertical current channels are likewise produced, although not by means of two gate electrodes 8, but rather by means of two drain electrodes 5.

FIG. 7 shows a cross section through two organic field-effect transistors stacked one on top of the other:

The construction from bottom to top shows the following layers of an integrated circuit:

The substrate 1 can be seen at the bottom, on which are applied the drain and source electrodes 4, 5 on the outer left and right and, surrounding them, the semiconductor layer 6. Situated on the semiconductor layer 6 is the first insulator layer 3. Seated on the latter is a gate electrode 8, which is linked via a contact lug 10 to a source and/or drain electrode 4, 5 of a lower transistor in such a way that, as soon as current flows through the semiconductor layer 6 there between drain and source electrode 4, 5, it is switched and a stack of transistors is correspondingly switched on, with the delay of a domino effect, by the application of current to the bottommost gate electrode 8. Situated above a gate electrode 8 is the second insulator layer 7, which enables the stack construction of the transistors.

The invention relates to an organic field-effect transistor with increased performance. The output current is increased by the construction of a plurality of current channels on the OFET which all supply a contribution to the output current. By not arranging the source and drain electrode on a plane parallel to the surface of the substrate, it becomes possible to realize smaller distances between source and drain than have previously been available. Shorter current channels with faster switching speeds thus result. Finally, the invention relates to integrated circuits in which the transistors are arranged in stacked fashion in a manner that saves space on a substrate.

1. An organic field-effect transistor on a substrate, at least one semiconducting layer connecting at least one drain and one source electrode, at least two insulating layers and at least one conductive layer with a gate electrode being applied on the substrate in such a way that after a voltage has been applied to the gate electrode, the field effect gives rise to at least two current channels and/or a current channel running vertically, that is to say transversely with respect to the surface of the substrate.

2. The organic field-effect transistor as claimed in claim 1, having at least two gate electrodes.

3. The organic field-effect transistor as claimed in claim 1 or 2, in which both sides of a gate electrode are used for producing two current channels.

4. The organic field-effect transistor as claimed in one of the preceding claims, in which at least two current channels with different geometries are present.

5. The organic field-effect transistor as claimed in one of the preceding claims, in which there is a short-circuiting circuit between at least two gate electrodes.

6. The organic field-effect transistor as claimed in one of the preceding claims, in which the first insulator layer and/or the drain electrode are applied in patterned fashion.

7. The organic field-effect transistor as claimed in one of the preceding claims, in which the patterning of the first insulator layer and the patterning of the drain electrode are identical.

8. The organic field-effect transistor as claimed in one of the preceding claims, in which the gate electrode is applied in patterned fashion.

9. An organic field-effect transistor having a distance between source and drain electrodes of less than 1 μm at least at one location.

10. An integrated circuit, which comprises at least one field-effect transistor as claimed in one of claims 1 to 9.

11. The integrated circuit, in which at least two transistors are arranged in stacked fashion.

12. The integrated circuit, in which the usable surface of the substrate is a multiple of its actual surface.

13. The integrated circuit as claimed in one of the preceding claims 10 to 12, which comprises at least two organic field-effect transistors.

14. The integrated circuit as claimed in one of the preceding claims 10 to 13, in which, with a stacked arrangement, the covering and/or encapsulation of a lower transistor serves as substrate and/or carrier of an upper transistor.

15. The integrated circuit as claimed in one of the preceding claims 10 to 14, in which the encapsulation of a lower transistor, with a stacked arrangement, has a thickness of greater than 200 nm.

16. A method for producing an integrated circuit by stacking and/or arranging one beside the other at least two transistors.

17. The method as claimed in claim 16, in which at least two organic field-effect transistors are stacked.

18. The uses of an integrated circuit having at least two transistors, which are arranged in stacked fashion, for constructing logic circuits.

19. A method for producing an OFET, comprising the following work steps:
application of a lower electrode to a substrate,
application of a first layer made of insulator to the lower electrode,
application of an upper electrode to the first insulator,
patterning of the upper electrode and of the first insulator layer; the patterning of the first insulating layer must be effected in one work step with the patterning of the drain/source and the structures must be identical at least at the edges at which a vertical current channel forms.
connection of the two electrodes by a coating with semiconducting material,
covering of the semiconducting layer with the second insulator,
application and patterning of the gate electrode to the second insulator at least where the semiconducting layer, connects the other two electrodes.

20. The method as claimed in claim 19, the bottom electrode likewise being patterned.

21. A method for producing a multiple channel OFET by applying patterned organic layers, for example polymers, to a substrate.

22. The method as claimed in claim 21, in which the patterned organic layers are applied to the substrate at least partly by printing.

23. The method as claimed in either of claims 21 and 22, in which the patterned polymer layers are applied to the substrate at least partly by spin-on, vapor deposition, and/or sputtering on with subsequent lithography.

24. The driving of organic DISPLAYS in integrated organic circuits for information processing with data rates of more than 200 bits, preferably from 1 000 bits (kbit) per second (integrated circuit having at least one OFET).

25. An RFID tag having at least one integrated circuit which comprises at least two transistors arranged in stacked fashion.
